(19) United States
(12) Patent Application Publication
(10) Pub. No.: US 2013/0009269 A1
(43) Pub. Date: Jan. 10, 2013

(54) ALIGNMENT MARKS AND ALIGNMENT METHODS FOR ALIGNING BACKSIDE COMPONENTS TO FRONTSIDE COMPONENTS IN INTEGRATED CIRCUITS

(76) Inventors: Gianluca Testa, Avezzano (IT); Giovanni De Amicis, L'Aquila (IT)

(21) Appl. No.: 13/309,809

(22) Filed: Dec. 2, 2011

Related U.S. Application Data
(60) Provisional application No. 61/505,491, filed on Jul. 7, 2011.

(51) Int. Cl. H01L 31/02; H01L 31/18

(52) U.S. Cl. 257/448; 438/70; 257/E31.127; 257/E31.113

(57) ABSTRACT

An imaging system may include an imager integrated circuit with frontside components such as imaging pixels and backside components. The imager integrated circuit may also include mirrored alignment marks formed with the frontside components. As part of forming the backside components, the integrated circuit may be flipped over such that the mirrored alignment marks are no longer mirrored and are readable by alignment systems. The formerly mirrored alignment marks may be used by the alignment systems in aligning the backside components with the frontside components in the imager integrated circuit (e.g., in forming the backside components in alignment with the frontside components).

This application claims the benefit of provisional patent application No. 61/505,491, filed Jul. 7, 2011, which is hereby incorporated by reference herein in its entirety.

### BACKGROUND

This relates generally to integrated circuits and, more particularly, to alignment marks and alignment methods for aligning backside components to frontside components.

Modern electronic devices such as cellular telephones, cameras, and computers often use digital image sensors. Imagers (i.e., image sensors) may be formed from a two-dimensional array of image sensing pixels. Each pixel receives incident photons (light) and converts the photons into electrical signals.

Modern imagers, and other integrated circuits, are sometimes formed from integrated circuits having frontside and backside components. The accuracy of conventional techniques for aligning frontside components to backside components, which typically rely upon infrared alignment systems not capable of accuracies less than one micrometers, are undesirable in at least some situations.

It would therefore be desirable to provide alignment marks and alignment methods for aligning backside components to frontside components in integrated circuits.

### BRIEF DESCRIPTION OF THE DRAWINGS

FIG. 1 is a diagram of an illustrative integrated circuit with image sensor circuitry that may include an integrated circuit having frontside and backside components and having alignment marks in accordance with an embodiment of the present invention.

FIG. 2 is a cross-sectional side view of an illustrative integrated circuit that may include frontside components such as photodiodes in accordance with an embodiment of the present invention.

FIG. 3 is a cross-sectional side view of the illustrative integrated circuit of FIG. 2 showing additional frontside layers that may be formed on the integrated circuit and that may include components such as metal lines, vias, and mirrored alignment marks such as mirrored combi marks in accordance with an embodiment of the present invention.

FIG. 4 is a cross-sectional side view of the illustrative integrated circuit of FIG. 3 and a bonding layer such as an oxide layer that may be formed on the integrated circuit.

FIG. 5 is a cross-sectional side view of an illustrative wafer such as a carrier wafer that may be stacked (e.g., bonded) to the illustrative integrated circuit of FIG. 4 in accordance with an embodiment of the present invention.

FIG. 6 is a cross-sectional side view of the illustrative wafer and integrated circuit of FIG. 5 showing how the integrated circuit may be etched to optically expose the mirrored alignment marks in accordance with an embodiment of the present invention.

FIG. 7 is a cross-sectional side view of the illustrative wafer and integrated circuit of FIG. 6 showing how backside components may be formed on the integrated circuit and how the backside components may be aligned with frontside components of the integrated circuit using the mirrored alignment marks in accordance with an embodiment of the present invention.

FIG. 8A is a top view of an illustrative mirrored alignment mark in accordance with an embodiment of the present invention.

FIG. 8B is a bottom view of the illustrative mirrored alignment mark of FIG. 8A in accordance with an embodiment of the present invention.

FIG. 9 is a flowchart of illustrative steps involved in aligning frontside and backside components in an integrated circuit in accordance with an embodiment of the present invention.

### DETAILED DESCRIPTION

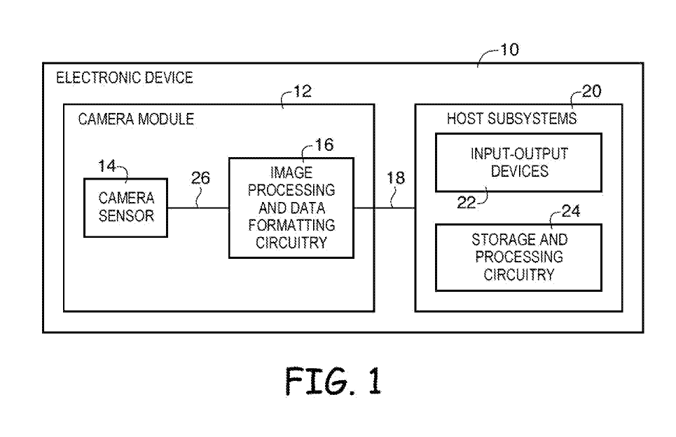

An electronic device is shown in FIG. 1. Electronic device 10 may have a digital camera module. Electronic device 10 may be a digital camera, a computer, a cellular telephone, a medical device, or other electronic device. Camera module 12 may include image sensor 14 and one or more lenses. During operation, the lenses focus light onto image sensor 14. Image sensor 14 includes photosensitive elements (i.e., pixels) that convert the light into digital data. Image sensors may have any number of pixels (e.g., hundreds, thousands, millions, or more). A typical image sensor may, for example, have millions of pixels (e.g., megapixels).

Still and video image data from camera sensor 14 may be provided to image processing and data formatting circuitry 16 via path 26. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip or SOC arrangement, camera sensor 14 and image processing and data formatting circuitry 16 are implemented on a common integrated circuit. The use of a single integrated circuit to implement camera sensor 14 and image processing and data formatting circuitry 16 can help to minimize costs.

Camera module 12 (e.g., image processing and data formatting circuitry 16) conveys acquired image data to host subsystem 20 over path 18. Electronic device 10 typically provides a user with numerous high-level functions. In a computer or advanced cellular telephone, for example, a user may be provided with the ability to run user applications. To implement these functions, host subsystem 20 of electronic device 10 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, etc.

Integrated circuits used to implement camera sensor 14 and, if sensor 14 and circuitry 16 are implemented on integrated chips together in a system on chip arrangement, image processing and data formatting circuitry 16 may be formed on a wafer (e.g., a silicon wafer) in a batch process. The camera sensors 14 on such a wafer, or any other integrated circuits in device 10, may be formed from integrated circuits having frontside and backside components aligned using mirrored alignment marks. The mirrored alignment marks may facilitate accurate alignment of the backside components to the frontside components (or vice-versa, depending on whether the frontside or backside components are formed first).

As one example, an integrated circuit may include a backside illuminated imager integrated circuit stacked together with a permanent carrier wafer. The backside illuminated imager integrated circuit may include backside structures such as light shields, color filters, lens structures, interconnects and circuitry, that may require alignment with photodiodes, circuitry, and other components formed on the frontside of the imager integrated circuit. Conventional techniques for aligning frontside and backside components in an integrated circuit rely typically upon infrared alignment systems having limited accuracies on the order of a few micrometers (e.g., 1-2 μm). Alignment marks described below in connection with various embodiments of the present invention may allow alignment of frontside and backside components in these and other types of integrated circuits with improved accuracies on the order of a few tens of nanometers (e.g., accuracies in the range of 30 to 40 nm, i.e., 0.03 to 0.04 μm). The higher accuracies provided by the various embodiments of the present invention may allow integrated circuits having frontside and backside components to be utilized in imaging applications and other applications requiring high levels of precision (e.g., applications that could not be implemented using traditional infrared alignment techniques).

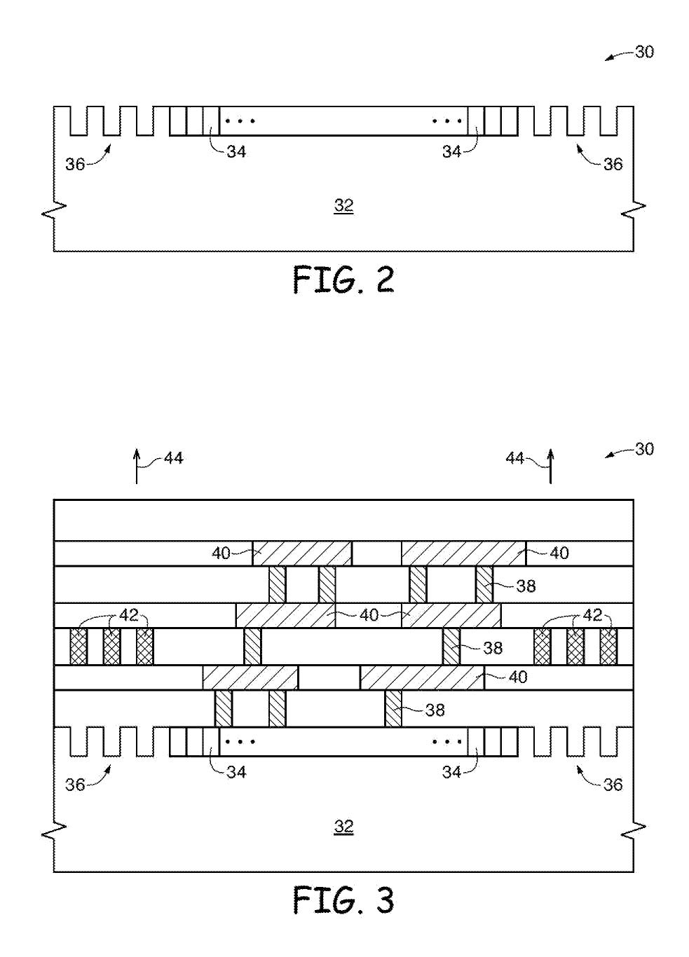

Portions of an illustrative integrated circuit 30 are shown in FIG. 2. Circuit 30 may be a camera sensor such as sensor 14 of FIG. 1 or may, in general, be another type of circuit.

Circuit 30 may include, as examples, substrate 32, components 34 formed in the frontside of substrate 32, and alignment marks 36. Substrate 32 may be a silicon substrate. Frontside components 34 may include, as examples, photodiodes, diodes, floating diffusion storage nodes, transistors such as reset transistors, source-follower transistors, reset transistors, transfer transistors, and row select transistors, and other integrated circuit components.

Alignment marks 36 may, as an example, be formed from openings etched into silicon substrate 32. If desired, the openings etched into silicon substrate 32 may be lined or filled with material to as part of forming alignment marks 36. With at least one suitable arrangement, alignment marks 36 may be formed from conventional alignment marks (e.g., conventional combi marks such as ASML alignment marks).

As shown in FIG. 3, layers of conductive vias 38 and lines 40 (e.g., layers V1, M1, V2, M2, etc.) may be formed above components 34 on the frontside of substrate 32. Any desired number of layers of metal vias and lines may be formed above substrate 32. Conductive vias 38 and lines 40 may interconnect components 34 with each other and may connect components 34 to other circuits and components (e.g., metal vias 38 and metal lines 40 may form part of path 26 coupling photodiodes 34 to external circuitry such as image processing and data formatting circuitry 16).

Circuit 30 may include mirrored alignment marks 42 within one or more of the layers of conductive vias and conductive lines. Mirrored alignment marks 42 may be aligned to (e.g., formed in alignment with) components 34 using alignment marks 36. With one suitable arrangement, mirrored alignment marks 42 may be formed from marks formed from a mirror image of conventional alignment marks (i.e., conventional combi marks). With this type of arrangement, alignment marks 42 may be unreadable by conventional alignment systems located above circuit 30 (e.g., in direction 44), while alignment marks 36 (at least prior to the formation of overlaying layers) may be readable by conventional alignment systems located above circuit 30.

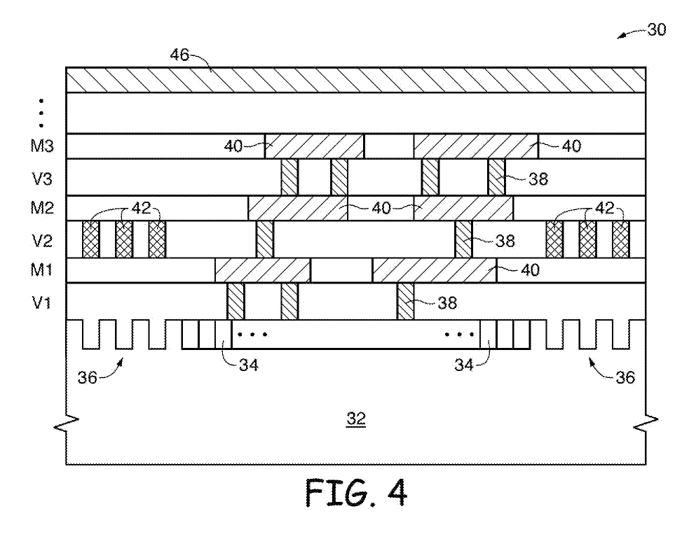

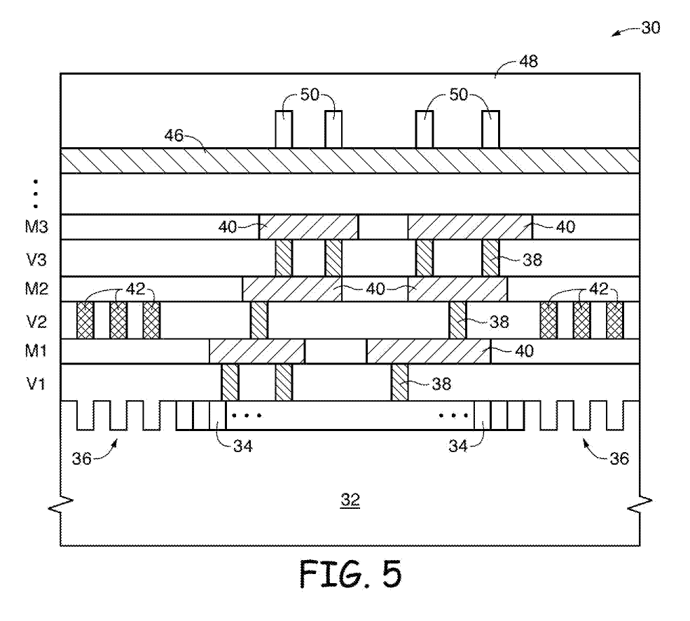

As shown in FIG. 4, a bonding layer such as oxide layer 46 may be formed on circuit 30. Oxide bonding layer 46 may be formed above metal via layers and metal interconnect layers. Oxide bonding layer 46 may, as an example, facilitate the bonding of a carrier wafer as shown in FIG. 5.

FIG. 5 illustrates how a wafer such as carrier wafer 48 may be bonded to bonding layer 46 (and substrate 32). Wafer 48 may, as examples, be a permanent carrier wafer or a temporary carrier wafer (e.g., a wafer bonded and then removed during manufacturing processes).

As shown in FIG. 5, permanent carrier wafer 48 may include structures such as alignment marks 50. Alignment marks 50 may facilitate the alignment of the notch of wafer 48 with the notch of substrate 32 during the bonding process with accuracies on the order of one micron. This allows the use of the notch of wafer 48 as a pre-alignment reference for all the future backside steps.

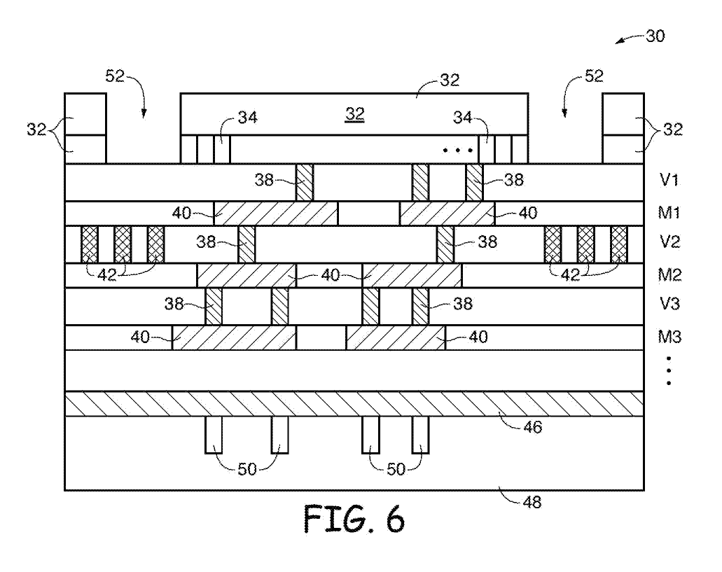

After carrier wafer 48 is bonded to substrate 32, the resulting stack may be flipped over for thinning of substrate 32 and additional processing. As shown in the FIG. 6 example, backside portions of substrate 32 above (previously underneath) components 34 may be etched away (e.g., only using the notch of wafer 48 for alignment, if desired), thereby creating openings 52 in substrate 32. Openings 52 may provide an optical path between mirrored alignment marks 42 and alignment systems.

The etching of substrate 32 along with any other desired backside processing steps may be aligned to integrated circuit 30 using mirrored alignment marks 42. While alignment marks 42 were initially mirrored (prior to flipping integrated circuit 30, as shown at least in FIG. 5), alignment marks 42 may be readable by conventional laser alignment systems such as ASML alignment systems once integrated circuit 30 is flipped (as shown at least in FIG. 6). Because of the relatively high accuracy of laser alignment systems (compared to infrared alignment systems), mirrored alignment marks 42 allow for more accurate alignment of processing operations (e.g., for accurate alignment of backside components to frontside components such as photodiodes 34) once the integrated circuit 30 is flipped into the orientation of FIG. 6, than could be provided using infrared alignment systems.

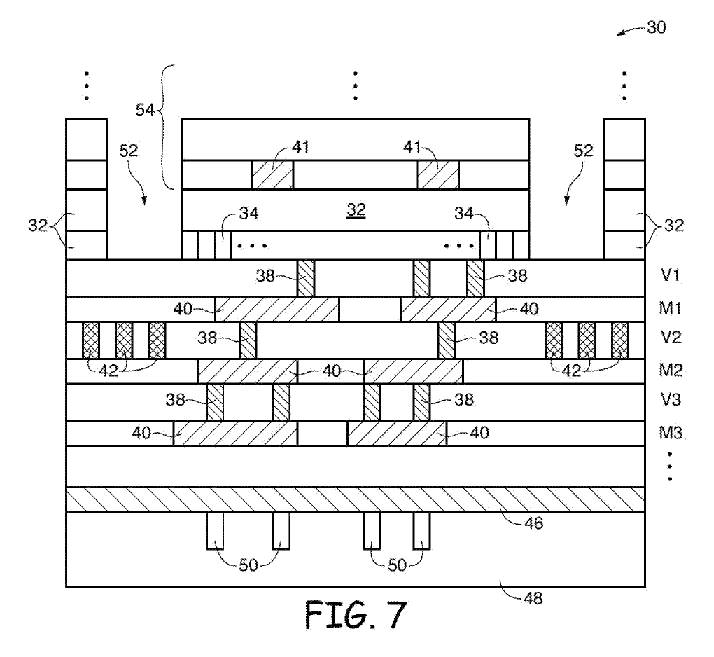

As shown in FIG. 7, additional layers 54 of components and materials may be formed on the backside of substrate 32. The backside components in layers 54 such as components 41 may be aligned to components 34 in the frontside of substrate 32 (and to components in the metal and via layers M1, V1, etc., components in carrier wafer 48, etc.) using alignment marks 42. As illustrative examples, components, structures, and materials (illustrated as structures 41 in FIG. 7) that may be formed on the backside of substrate 32 (e.g., on the backside of a backside illuminated imager device) may include imaging (photo) layers such as color filters, light shield, backside circuitry and interconnects, passivation layers, lenses, microlenses, anti-reflection layers, light blocking structures (e.g., structures that reduce optical cross-talk), etc. If desired, backside color filter layers may include an array of color filters, each of which is aligned with a respective image sensing pixel in an array of backside illuminated image sensing pixels (formed on the frontside of substrate 32). In embodiments in which integrated circuit 30 is a device other than an imaging device, any desired components, structures, and materials may be formed on the backside of wafer 32 and, if desired, alignment marks 42 may be used in aligning those structures to wafers 32 and 48 (e.g., to frontside components in substrate 32). While many embodiments herein are described in the context of imagers, the embodiments described herein apply, in general, to all different types of integrated circuits.

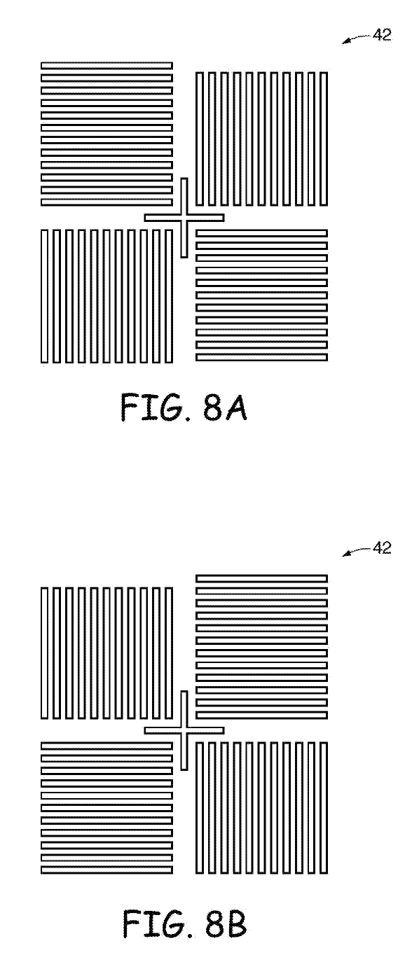

An illustrative example of a mirrored alignment mark 42 is shown in FIGS. 8A and 8B. Mirrored alignment mark 42 may be formed in the mirror image of conventional combi alignment marks. With this type of arrangement, when mirrored alignment mark 42 is viewed from above (as shown in FIG. 8A and as illustrated by direction 44 in FIG. 3), conventional alignment systems may be unable to read (e.g., align to) mirrored alignment mark 42. However, after substrate 32 is flipped over for further processing (e.g., for backside processing, as shown in FIG. 6), mirrored alignment marks 42 may be flipped into a form (shown in FIG. 8B) that is readable by the conventional alignment systems (e.g., alignment systems that read mirrored alignment marks 42 through optical path 52, shown in FIG. 6). As a result, mirrored alignment marks 42 may be used in forming backside components with very high levels of accuracy in their alignment to frontside components (e.g., levels of accuracy similar to the levels of accuracy that can be achieved when aligning frontside components to frontside components).

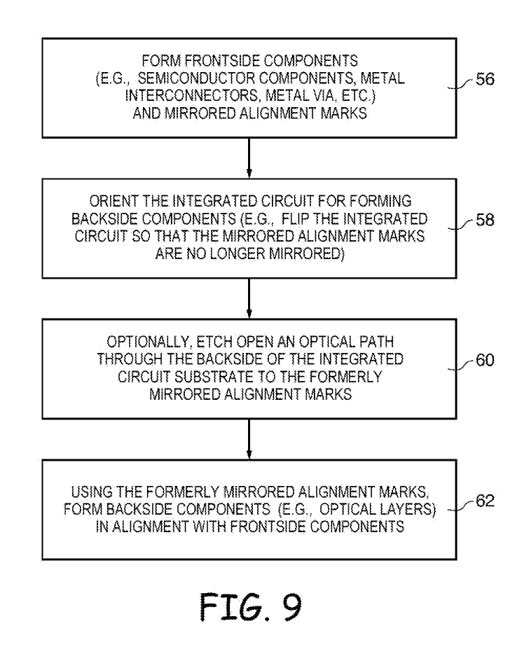

A flowchart of illustrative steps involved in forming backside components aligned with frontside components in an integrated circuit is shown in FIG. 9.

In step 56, frontside components in integrated circuit 30 such as semiconductor components 34, metal vias 38, and metal line 40 may be formed. Also in step 56, mirrored alignment marks such as mirrored alignment marks 42 may be formed (e.g., mirrored alignment marks 42 may be formed in the pattern of FIG. 8A, which may be unreadable by conventional alignment systems when viewed from above).

In step 58, integrated circuit 30 may be oriented (e.g., flipped) into an orientation in which backside components may be formed on substrate 32. Once integrated circuit 30 is flipped over, mirrored alignment marks 42 may have an appearance such as that shown in FIG. 8B, which may be readable by conventional alignment systems. Mirrored alignment marks 42 that have been flipped to have an appearance such as that shown in FIG. 8B may sometimes be referred to herein as mirrored and flipped alignment marks.

In step 60, an optical path such as path 52 may be etched open in the backside of integrated circuit 30 (e.g., the backside of wafer 32). The optical path may facilitate the reading of mirrored and flipped alignment marks by alignment systems, during the formation of backside components, structures, and circuits.

In step 62, backside components may be formed on wafer 32. The backside components may include, as examples, optical layers such as light shields, color filters, lens structures, interconnects and circuitry, circuitry, and other components formed on the backside of the imager integrated circuit that may require alignment with frontside components such as photodiodes. The backside components may be aligned to frontside components, formed in step 56, using the mirrored and flipped alignment marks (e.g., alignment marks 42).

Various embodiments have been described illustrating alignment marks and alignment methods for aligning backside components to frontside components in integrated circuits.

An imaging system may include an imager integrated circuit with frontside components such as backside illuminated imaging pixels and backside optical layers.

While forming the frontside components, mirrored alignment marks, which are unreadable by alignment systems when viewed from above, may be formed in the integrated circuit. As part of the forming the backside components, the integrated circuit may be flipped over such as the mirrored alignment marks are consequently readable by alignment systems when viewed from above. Lithographic processes used in forming the backside components (e.g., patterned light exposures) may be aligned to the integrated circuit (e.g., to frontside components) using the mirrored and flipped alignment marks.

The foregoing is merely illustrative of the principles of this invention which can be practiced in other embodiments.

What is claimed is:

1. A method comprising:
forming frontside components on a first side of a substrate;
forming mirrored alignment marks on the first side of the substrate;
flipping the substrate over; and
forming backside components on a second side of the substrate, wherein forming the backside components comprises aligning the backside components to the frontside components using the mirrored alignment marks.

2. The method defined in claim 1 wherein the mirrored alignment marks are unreadable by an alignment system when viewed from the first side of the substrate.

3. The method defined in claim 1 wherein the mirrored alignment marks are readable by an alignment system when viewed from the second side of the substrate and are readable by the alignment system when viewed from the first side of the substrate.

4. The method defined in claim 1 wherein forming the frontside components comprises forming an array of image sensing pixels.

5. The method defined in claim 4 wherein forming the backside components comprises forming a color filter layer.

6. The method defined in claim 1 wherein forming the frontside components comprises forming an array of backside illuminated image sensing pixels and forming metal interconnects and vias connected to the image sensing pixels.

7. A method of aligning backside components to frontside components in an integrated circuit, the method comprising:
forming alignment marks on a frontside of the integrated circuit, wherein the alignment marks are unreadable by an alignment system when viewed from the frontside of the integrated circuit;
flipping over the integrated circuit with the alignment marks; and
using the alignment system to read the alignment marks from a backside of the integrated circuit.

8. The method defined in claim 7 further comprising:
prior to forming the alignment marks, forming the frontside components.

9. The method defined in claim 8 further comprising:
after using the alignment system to read the alignment marks from the backside of the integrated circuit, forming the backside components in alignment with the frontside components in the integrated circuit.

10. The method defined in claim 8 wherein forming the frontside components comprises forming an array of backside illuminated image sensing pixels.

11. The method defined in claim 10 wherein forming the backside components comprises forming an array of color filters, each of which is aligned above a respective one of the image sensing pixels.

12. The method defined in claim 11 wherein the alignment marks comprises first, second, third, and fourth groups of lines, wherein the first and fourth groups of lines are parallel to each other, and wherein the second and third groups of lines are parallel to each other and perpendicular to the first and fourth groups of lines.

13. An imager integrated circuit comprising:
a substrate having a first side and a second side;
a plurality of semiconductor components located on the first side of the substrate;
mirrored alignment marks on the first side of the substrate; and
at least one component on the second side of the substrate, wherein the mirrored alignment marks are unreadable by an alignment system when the substrate is in a first orientation and the alignment system is above the first side of the substrate and wherein the mirrored alignment marks are readable by the alignment system when the substrate is flipped over into a second orientation and the alignment system is above the second side of the substrate.

14. The imager integrated circuit defined in claim 13 wherein the semiconductor components comprise an array of image sensing pixels.

15. The imager integrated circuit defined in claim 14 wherein the semiconductor components comprise reset transistors, transfer transistors, floating diffusion storage nodes, and source-follower transistors.

16. The imager integrated circuit defined in claim 13 further comprising a plurality of layers of metal interconnects and vias electrically coupled to the semiconductor components located on the first side of the substrate.

17. The imager integrated circuit defined in claim 16 wherein the imager integrated circuit is bonded to a carrier wafer.

18. The imager integrated circuit defined in claim 16 wherein the imager integrated circuit is bonded to a carrier wafer with an oxide bonding layer.

19. The imager integrated circuit defined in claim 16 wherein the imager integrated circuit is bonded to a carrier wafer having alignment marks.
